(19) United States
(12) Patent Application Publication
(10) Pub. No.: US 2024/0318983 A1
(43) Pub. Date: Sep. 26, 2024

(54) MAGNETIC MULTI-TURN SENSOR

(71) Applicant: Analog Devices International Unlimited Company, Limerick (IE)

(72) Inventors: Jochen Schmitt, Biedenkopf (DE); Jan Kubik, Limerick (IE); Fernando Franco, Limerick (IE)

(21) Appl. No.: 18/612,903

(22) Filed: Mar. 21, 2024

Related U.S. Application Data
(60) Provisional application No. 63/491,643, filed on Mar. 22, 2023.

(51) Int. Cl. G01D 5/16

(52) U.S. Cl. CPC G01D 5/16

(57) ABSTRACT

The present disclosure provides a magnetic multi-turn sensor that makes use of a divider type structure. In this respect, a magnetoresistive track is laid out in a loop comprising a plurality of divider portions along at least one side of the loop, the divider portions each being formed as a loop or an arch of magnetoresistive material. Adjacent divider portions are connected by a connecting loop of magnetic material. The legs of the connecting loop are formed over the top of the legs of the divider portions, to thereby form connecting legs with dead ends. In some examples, in the region of the connecting legs, a spacer is also provided between the magnetoresistive track and the magnetic connecting loop. In further arrangements described herein, a siphon structure is provided before the Y-junction of adjacent divider portions.

### INCORPORATION BY REFERENCE TO ANY PRIORITY APPLICATIONS

This application claims the benefit of priority of U.S. Provisional Application No. 63/491,643 filed Mar. 22, 2023, the content of which is hereby incorporated by reference herein in its entirety. Any and all applications for which a foreign or domestic priority claim is identified in the Application Data Sheet as filed with the present application are hereby incorporated by reference under 37 CFR 1.57.

### BACKGROUND

### Technical Field

The present disclose relates to magnetic multi-turn sensors. In particular, the present disclosure relates to a divider structure for use in a magnetic multi-turn sensor and a method of manufacture thereof.

### Description of the Related Technology

Magnetic multi-turn sensors are commonly used in applications where there is a need to monitor the number of times a device has been turned. An example is a steering wheel in a vehicle. Magnetic multi-turn sensors typically include magnetoresistance elements that are sensitive to an applied external magnetic field. The resistance of the magnetoresistance elements can be changed by rotating a magnetic field within the vicinity of the sensor. Variations in the resistance of the magnetoresistance elements can be tracked to determine the number of turns in the magnetic field, which can be translated to a number of turns in the device being monitored.

Magnet multi-turn sensors typically comprise a plurality of magnetoresistive elements laid out as a strip in a spiral or closed loop configuration.

Other magnetic multi-turn sensors make use of a divider type structure, where the sensor comprises at least one closed loop of magnetoresistive material with a plurality of divider loops.

### SUMMARY

The present disclosure provides a magnetic multi-turn sensor that makes use of a divider type structure. In this respect, a magnetoresistive track is laid out in a loop comprising a plurality of divider portions along at least one side of the loop, the divider portions each being formed as a loop or an arch of magnetoresistive material. Adjacent divider portions are connected by a connecting loop of magnetic material. The legs of the connecting loop are formed over the top of the legs of the divider portions, to thereby form connecting legs with dead ends. In some examples, in the region of the connecting legs, a spacer is also provided between the magnetoresistive track and the magnetic connecting loop. In further arrangements described herein, a siphon structure is provided before the Y-junction of adjacent divider portions.

A first aspect of the present disclosure provides a closed-loop magnetic multi-turn sensor, comprising one or more magnetoresistive tracks comprising a plurality of magnetoresistive looped portions, and one or more connecting loops for connecting adjacent magnetoresistive looped portions, the one or more connecting loops comprising a track of magnetic material, wherein the magnetoresistive looped portions and the one or more connecting loops are coupled to form a plurality of connecting legs, wherein each connecting leg comprises a portion of a connecting loop formed in a first plane and at least a portion of a magnetoresistive looped portion arranged in a second plane.

By providing connecting loops of magnetic material to connect the loops of the magnetoresistive film and thereby form a closed-loop, the need for a Y-junction of magnetoresistive material where domain nucleation can occur is eliminated, whilst still enabling domain walls to propagate around the closed-loop to thereby facilitate multi-turn sensing of a rotating external magnetic field. In this respect, the plurality of magnetoresistive looped portions are arranged in a first plane and the one or more connecting loops are arranged in a second plane. For example, the second plane may be above the first plane. That is to say, in the region of the connecting legs, the connecting loops may be formed on top of the magnetoresistive looped portions. Similarly, the second plane may be below the first plane. That is to say, in the region of the connecting legs, the connecting loops may be formed below the magnetoresistive looped portions.

The plurality of connecting legs may comprise a dead end. In some cases, the dead end may comprise a sharpened end. By providing a sharpened end, this helps to prevent unwanted domain wall nucleation in the end region of the connecting legs.

The plurality of connecting legs may each comprise a spacer layer provided between at least a first portion of the magnetoresistive looped portion and a corresponding portion of the respective connecting loop. The spacer helps to ensure that shape anisotropy is not reduced as a result of ferromagnetic coupling between the magnetoresistive looped portion and the connecting loop. A second portion of the magnetoresistive looped portion may be in direct contact with the respective connecting loop, the second portion being in an end region of the connecting leg. That is to say, in the end region of the connecting loop, there may be no spacer layer provided between the magnetoresistive looped portion and the connecting loop to thereby provide good electrical connection and ferromagnetic coupling. In some examples, the spacer layer may comprise one of: aluminium oxide, silicon nitride, silicon oxide, Tantalum, Ruthenium, Titanium and Titanium Tungsten.

The one or more connecting loops may be in an offset position relative to the plurality of magnetoresistive looped portions. In doing so, more space along the magnetoresistive looped portions is provided for placing electrical contacts for sensor read-out.

The one or more connecting loops may have a same width as the one or more magnetoresistive tracks.

The magnetic material of the one or more connecting loops may be a ferromagnetic material. For example, the magnetic material of the one or more connecting loops may comprise one of Nickel, Iron, or Cobalt, or an alloy containing at least one of Nickel, Iron, or Cobalt.

The one or more magnetoresistive tracks may comprise one of: a giant magnetoresistive (GMR) material and a tunnel magnetoresistive (TMR) material.

The one or more magnetoresistive tracks and the one or more connecting loops may be formed on a substrate. For example, the substrate may comprise a silicon or glass substrate. It will also be appreciated that the sensor may be disposed on a printed circuit board (PCB) comprising processing circuitry for processing the turn count signal.

The closed-loop magnetic multi-turn sensor may further comprise a plurality of contacts for electrically connecting the one or more magnetoresistive tracks, such that a plurality of magnetoresistive sensor elements connected in series are defined by said contacts.

A further aspect of the present disclosure provides a method of manufacturing a closed-loop magnetic multi-turn sensor, the method comprising forming a film of magnetoresistive material on a substrate, etching the film of magnetoresistive material to form a magnetoresistive track comprising a plurality of magnetoresistive looped portions, forming, over the magnetoresistive track, a first photoresist layer, exposing the first photoresist layer to form one or more openings, the one or more openings being formed between adjacent magnetoresistive looped portions, and depositing a magnetic material in the one or more openings to form one or more connecting loops between adjacent magnetoresistive looped portions, wherein a portion of each connecting loop is coupled to a portion of a magnetoresistive looped portion to form a connecting leg.

For example, a portion of the connecting loop may be formed over the top of a portion of the magnetoresistive looped portion to form the connecting leg.

Each connecting leg may comprise a dead end, the method further comprising sharpening each dead end.

The method may further comprise depositing a spacer layer between the magnetoresistive looped portions and the one or more connecting loops. For example, the spacer layer may comprise one of: aluminium oxide, silicon nitride, silicon oxide, Tantalum, Ruthenium, Titanium and Titanium Tungsten.

The magnetic material may be a ferromagnetic material. For example, the magnetic material may comprise one of Nickel, Iron, or Cobalt, or an alloy containing at least one of Nickel, Iron, or Cobalt.

Another aspect of the present disclosure provides a closed-loop magnetic multi-turn sensor, comprising one or more magnetoresistive tracks comprising a plurality of magnetoresistive looped portions, each magnetoresistive track at least comprising a first magnetoresistive looped portion comprising a first S-shaped connecting region and a first straight connecting region, and a second magnetoresistive looped portion comprising a second S-shaped connecting region and a second straight connecting region, wherein the second straight connecting region is connected to the first straight connecting region to form a connection point having a portion of magnetoresistive track extending therefrom.

The first S-shaped connecting region may extend away from the second S-shaped connecting region.

The first and second connecting straight regions may diverge from the connection point with an angle β relative to the portion of magnetoresistive track extending from the connection point. For example, the angle β may be less than 45°.

The first and second connection straight regions may have a first width, and the portion of magnetoresistive track extending from the connection point may have a second width, the first width being substantially the same as the second width.

A further aspect of the present disclosure provides a closed-loop magnetic multi-turn sensor, comprising one or more magnetoresistive tracks comprising a plurality of magnetoresistive looped portions, each magnetoresistive track at least comprising a first magnetoresistive looped portion comprising a first straight connecting region having a first width, and a second magnetoresistive looped portion comprising a second straight connecting region having a second width, wherein the second straight connecting region is connected to the first straight connecting region to form a connection point, a portion of magnetoresistive track extending therefrom, the portion of magnetoresistive track having a third width, wherein the first and second widths are substantially the same as the third width.

### BRIEF DESCRIPTION OF THE DRAWINGS

The present disclosure will now be described by way of example only with reference to the accompanying drawings.

FIG. 1 illustrates a divider type magnetic structure and its operation according to prior art.

FIG. 2 further illustrates a magnetic multi-turn sensor comprising a plurality of divider structures according to the prior art.

FIG. 3 illustrates a portion of a divider structure according to prior art.

FIG. 4 illustrates a divider structure for a magnetic multi-turn sensor according to the present disclosure.

FIGS. 5A-5H illustrate an example method of manufacturing a divider structure for a magnetic multi-turn sensor according to the present disclosure.

FIGS. 6A-B illustrate the structure of a divider structure of a magnetic multi-turn sensor according to the present disclosure.

FIGS. 7A and 7B further illustrate examples of a divider structure for a magnetic multi-turn sensor according to the present disclosure.

FIG. 8 illustrates example readout locations on a divider structure of a magnetic multi-turn sensor according to the present disclosure.

FIGS. 9A-B illustrate an example method for initialising a divider structure of a magnetic multi-turn sensor according to the present disclosure.

FIG. 10 illustrates a further example of a divider structure for a magnetic multi-turn sensor according to the present disclosure.

FIGS. 11A-B illustrate example readout locations on a divider structure of a magnetic multi-turn sensor according to the present disclosure.

FIGS. 12A-C illustrate further examples of divider structures for use in a magnetic multi-turn sensor c according to the present disclosure.

FIGS. 13A-B illustrate a further example of a divider structure according to the present disclosure.

FIGS. 14A-E illustrate a further example method of manufacturing a divider structure for a magnetic multi-turn sensor according to the present disclosure.

FIG. 15 illustrates a further example of a divider structure for use in a magnetic multi-turn sensor according to the present disclosure.

### DETAILED DESCRIPTION

Magnetic multi-turn sensors can be used to monitor the turn count of a rotating shaft. To do this, a magnet is typically mounted to the end of the rotating shaft, the multi-turn sensor being sensitive to the rotation of the magnetic field as the magnet rotates with the shaft. Such magnetic sensing can be applied to a variety of different applications, such as automotive applications, medical applications, industrial control applications, consumer applications, and a host of other applications which require information regarding a position of a rotating component.

Magnetic multi-turn sensors typically include giant magnetoresistive (GMR) elements or tunnel magnetoresistive (TMR) elements that are sensitive to an applied external magnetic field arranged in a spiral or closed loop configuration.

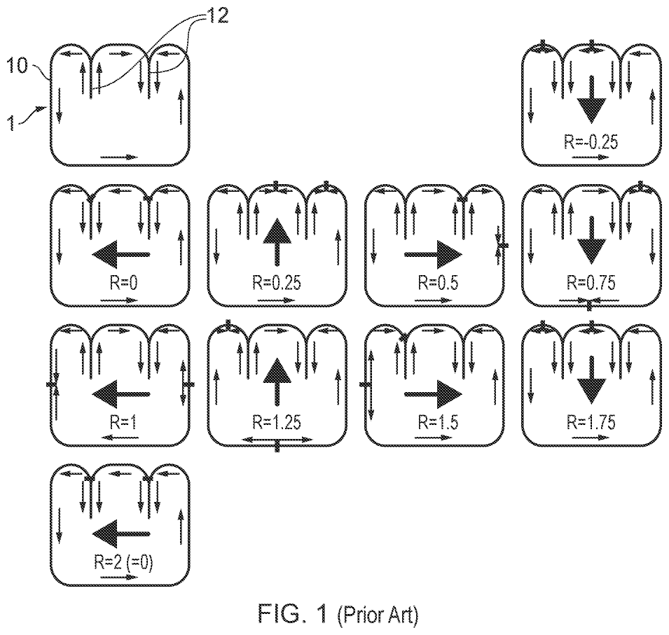

Another type of magnetic multi-turn sensor 1 makes use of a divider type structure, as illustrated by FIG. 1. Here, the magnetoresistive track 10 is laid out in at least one closed loop with a plurality of divider loops along at least one side of the closed loop. As shown in FIG. 1, domain walls propagate around the magnetoresistive track 10 as an external magnetic field (denoted by the large arrow) rotates, such that the magnetisation states of each section of the track 10 (denoted by the small arrows) change with magnetic field rotation.

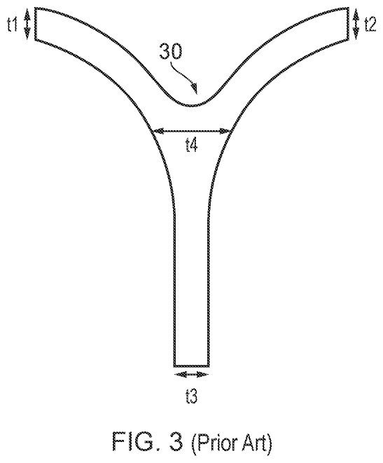

In these divider type structures for use in a magnetic multi turn sensor, the divider loops include a plurality of ‘dead ends’ 12. In this regard, the dead ends 12 are proceeded by two curved magnetoresistive tracks meeting to create a Y-shaped junction 30, as further illustrated by FIG. 3.

As the domain walls are propagating around the divider type sensor 1, the domain walls are split into two domains walls (e.g., when they are somewhere along a loop). After one rotation, one of the domain walls will propagate along the dead end 12 and disappear at the tip, whilst the other will be stopped around the Y-junction 30 and then released after an additional rotation. The number of dead ends 12 and Y-junctions 30 in the divider type structure thus determines the amount of turns a magnetic field needs to be rotated to get back to the original state.

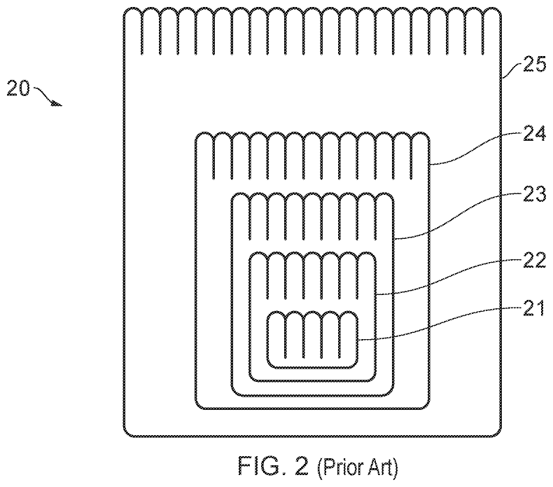

Consequently, these structures can be used to measure counts of a rotating field. The limitation of counts for a single loop 10 is given by the number, N, of dead ends 12 added to the loop 10. Thus, it needs N+1 turns to return to the original magnetic state. As illustrated by the multi-turn sensor 20 shown in FIG. 2, by combining multiple of these divider structures 21-25 with prime numbers of count ranges (i.e., as defined by the number of dead ends), the overall count ranges can be enhanced. In this respect, the resulting count range is a multiplication of the individual count range of each structure 21-25.

However, one of the main problems with this divider structure is the area where two arms of each dividing loops join, i.e., the Y-junction 30 shown in FIG. 3. The width of the Y-junction track, t4, can be up to twice as wide, or at least substantially wider, as the tracks in other areas of sensor, t1-t3. Additionally, there is often a rounding of the magnetoresistive material at the Y-junction 30. As such, the Y-junction causes a lack of width uniformity in the magnetoresistive track.

As a result, the shape anisotropy is significantly reduced in this Y-junction area such that domain wall nucleation at lower magnetic fields compared to the other areas of the sensor is inevitable in these regions, which limits the useful magnetic window of operation. That is to say, at lower magnetic fields, domain walls will more readily nucleate in these Y-junctions, causing the sensor to operate incorrectly.

The present disclosure therefore provides a divider type structure for use with a magnetic multi turn sensor with improved uniformity of magnetoresistive tracks even at the Y-junction. This seeks to combat the effects of reduced shape anisotropy in this area and therefore prevent domain wall nucleation at lower fields. In particular, the present disclosure provides an arrangement in which adjacent divider loops are coupled together by a connecting loop of magnetic material that lies on top of the magnetoresistive material of each dead end.

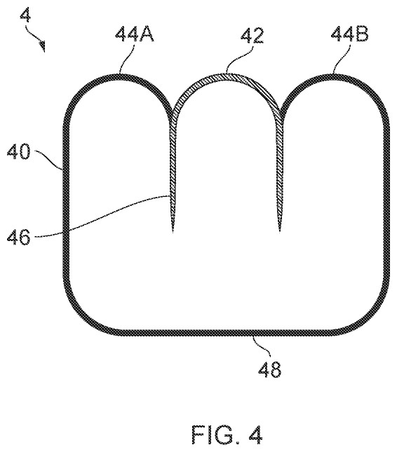

FIG. 4 illustrates a divider type structure 4 for use with a magnetic multi turn sensor in accordance with an example of the present disclosure. In this respect, it will be appreciated that a multi-turn sensor may comprise one of more of these divider type structures 4, with varying numbers of looped portions as described above (e.g., as shown in FIG. 2). In this example, the divider type structure 4 is formed of a magnetoresistive track 40 comprising at least two magnetoresistive looped portions 44A-B and one or more connecting loops 42 formed from a ferromagnetic material or some other suitable magnetic material. In this example, the magnetoresistive track 40 is formed such that a substantially straight length 48 of magnetoresistive material connects the magnetoresistive looped portions 44A-B to thereby form a closed loop. As will be described further below, it will however be appreciated that the magnetoresistive looped portions may be provided on more than one “side” of the magnetoresistive track. In this example, the connecting loop 42 is formed partly on top of the magnetoresistive looped portions 44A-B of the magnetoresistive track 40 i.e., in a second plane, to thereby form a dead end 46 (i.e., a connecting leg). That is to say, the dead ends 46 each comprise a leg of the connecting loop 42 and a leg of a magnetoresistive looped portion 44A-B of the magnetoresistive track 40, with the leg of the connecting loop 42 overlaying the leg of the looped portion 44A-B. Alternatively, it will be appreciated that the connecting loop 42 may arranged below such that the legs of the magnetoresistive looped portions 44A-B overlay the legs of the connecting loop 42. Either way, the dead ends 42 will comprise a leg of a magnetoresistive looped portions 44A-B arranged in a first plane, and a leg of a connecting loop 42 arranged in a second plane, the second plane being above or below the first plane. It will also be appreciated that the connecting loop 42 is not utilised for any resistive readouts for the sensor operation and that the connecting loop 42 does not need to be formed from a magnetoresistive material. However, the connecting loop 42 is formed from a ferromagnetic material or some other magnetic material to allow magnetic domain walls to propagate around the track 40 without affecting the operation of the sensor. Additionally, it can be seen that the tips of the dead ends 46, that is, the end point at which a magnetoresistive looped portion 44A-B and its respective connecting loop 42 meet, are sharpened. By providing the tips of the dead ends 46 with a sharpened end, this helps to prevent unwanted domain wall nucleation in this end region. In this respect, if the dead ends 46 have not been sharpened, this can result in areas where magnetic domains are created at an angle (rather than parallel to the length of the magnetoresistive track 40), which can make those domains more prone to rotation. The sharper the angle of the tip of the dead ends 46, the less domains that are formed that are susceptible to an unwanted change in magnetic moment direction at lower magnetic fields.

The connecting loop 42 may be formed of any suitable magnetic material. This material may be a soft-ferromagnetic material, for example, comprising one of Nickel, Iron, or Cobalt, or an alloy containing at least one of Nickel, Iron, or Cobalt.

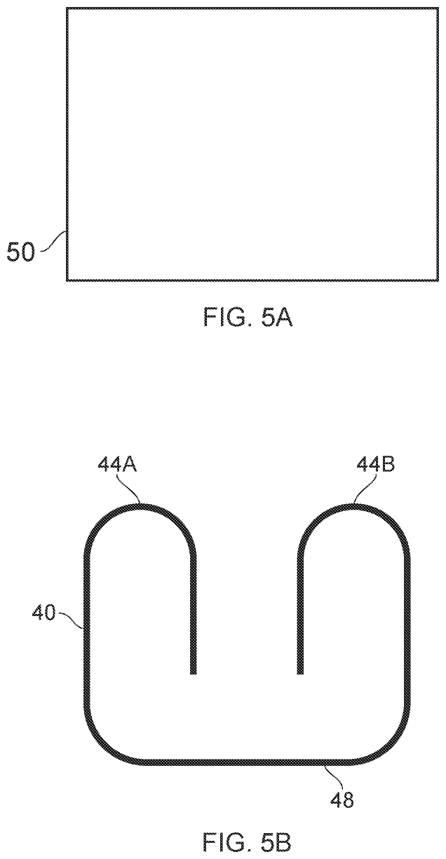

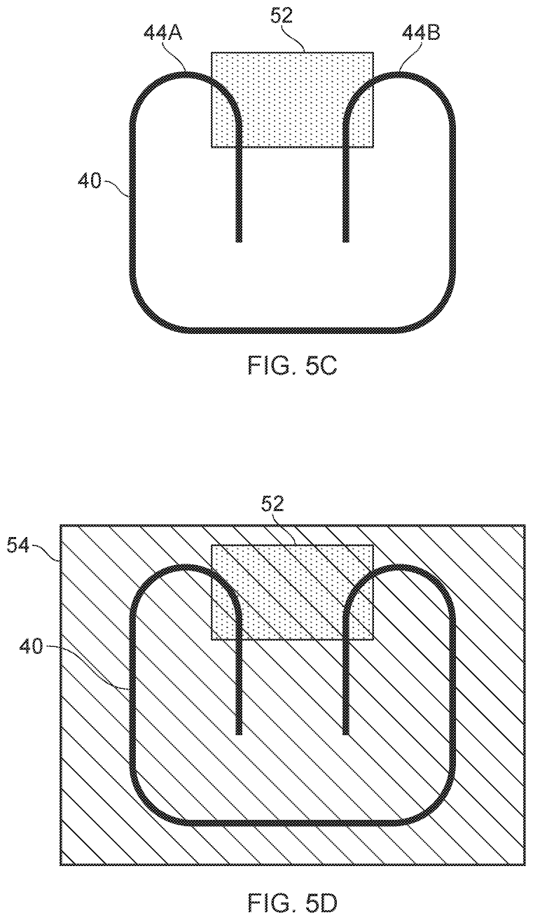

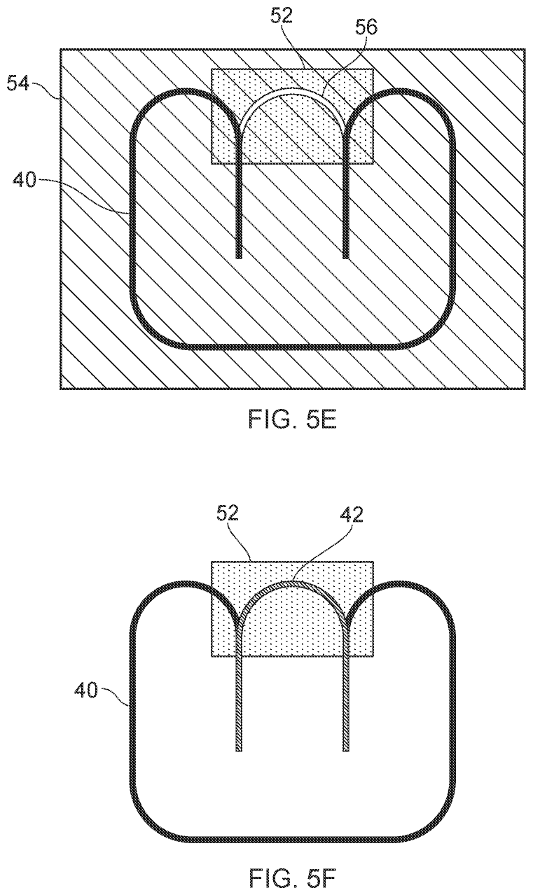

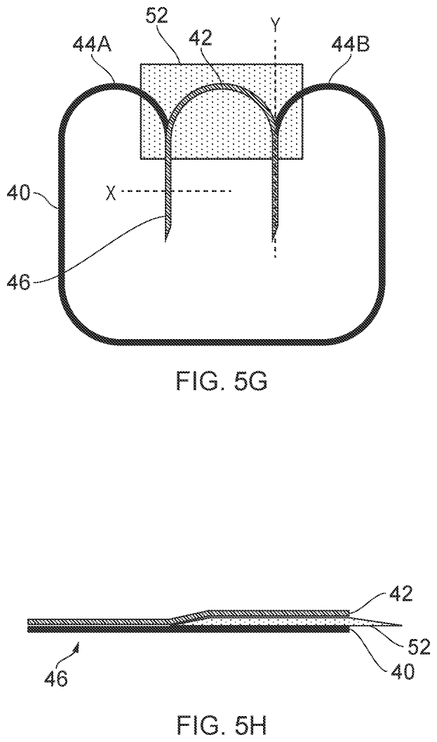

An example of a method of fabricating the divider structure of FIG. 4 is illustrated in FIGS. 5A-5H. FIG. 5A shows the first step of the fabrication process in which a blanket magnetoresistive film 50 is deposited, for example, on a substrate such as a silicon wafer or a glass substrate. It will be appreciated that once the sensor has been fabricated, it may be disposed on a printed circuit board (PCB) comprising processing circuitry for processing the sensor signal. It will be appreciated that the magnetoresistive film 50 may be a giant magnetoresistive (GMR) or tunnel magnetoresistive (TMR) film.

As shown in FIG. 5B, the magnetoresistive track 40 is patterned to form one or more magnetoresistive looped portions 44 and a substantially straight length 48 that connects the end magnetoresistive looped portions 44A-B. In this respect, once the film 50 has been deposited uniformly, the film 50 is etched to form the magnetoresistive track 40, for example, using milling, ion beam etching or reactive-ion etching. For the looped portions of the magnetoresistive tracks 40, the etch may be performed at an angle to etch the film 50 in a uniform manor. It will of course be appreciated that any suitable angle may be used, depending on the requirements of the track 40. Likewise, it will also be appreciated that other methods of etching the tracks 40 may also be used.

As shown in FIG. 5C, a spacer layer 52 is placed on top of a portion of the magnetoresistive track 40, specifically, between two looped portions 44A-B, which will ensure that the connecting loop 42 is formed above the magnetoresistive looped portion 44A-B, and provides an isolating material between the magnetoresistive looped portion 44A-B and the connecting loop 42 in the region of the connection junction. The spacer layer 52 may be formed of any suitable material, for example, aluminium oxide (Al2O3), silicon nitride (Si3N4), silicon oxide (SiO2), Tantalum, Ruthenium, Titanium or Titanium Tungsten.

As shown in FIG. 5D, a photoresist layer 54 is then formed on top of the whole arrangement, for example, using a spin coating process. As shown in FIG. 5E, an opening 56 is created within the photoresist layer 54. That is to say, a region 56 of the photoresist layer 54 is removed. For example, this may be done by UV light exposure through a mask or via ion-beam lithography, or any other suitable method. The photoresist layer 54 is then developed using a suitable solution, which leaves a U-Shape opening in the photoresist layer 54, as shown in FIG. 5E.

As shown in FIG. 5F, the connecting loop 42 is formed by filling in the opening 56 with a magnetic material, for example, using a sputtering technique, and lifting off the remaining photoresist layer 54. Finally, as shown in FIG. 5G, the tips of the dead ends 46 (i.e., the connecting legs of the magnetoresistive looped portions 44A-B and connecting loop 42) are sharpened. This may be done through a process of a photoresist spin coating, UV-light exposure with a mask, developing the photoresist, etching through the tracks, and then removing the photoresist. The tips of the dead ends 46 need to be sharpened to ensure unwanted domain wall nucleation does not occur at lower magnetic fields. The sharper the angle of the tip of the dead ends 46, the higher the field required to form a domain wall at this location.

FIG. 5H shows a cross-section along the axis Y (as shown in FIG. 5G). As can be seen, the resulting connecting legs comprise a portion of the magnetoresistive track 40 (i.e., a leg of a looped portion 44A-B), the spacer layer 52 and the magnetic material of the connecting loop 42. At the tip of the dead end 46, the magnetic material 42 lies directly on top of the magnetoresistive track 40 to provide a good electrical connection and ferromagnetic coupling to thereby increase the shape anisotropy in this region and prevent unwanted domain wall nucleation. It will however be appreciated that the spacer layer 52 has a thickness in the region of nanometres or even sub-nanometres, and hence its presence does not negatively affect the magnetisation between the connecting loop 42 and the magnetoresistive track 40. As such, it is clear that the magnetoresistive track 40 lies in a first plane, whilst the connecting loop 42 sits above the magnetoresistive track 40 in a second plane.

In the region of the Y-junction, where the magnetoresistive track 40 and connecting loop 42 diverge, any ferromagnetic coupling between the magnetoresistive track 40 and connection loop 42 can create the effect of a single wider track, thus reducing the shape anisotropy in this region and creating unwanted domain wall nucleation sites at lower magnetic fields compared to the rest of the magnetoresistive track 40. By providing a spacer layer 52 in the region of the Y-junction, this helps to ensure that shape anisotropy is not reduced as a result of ferromagnetic coupling between the magnetoresistive track 40 and the connecting loop 42 in this region. As such, the spacer layer 52 helps to provide a uniform connection between the connecting legs of the magnetoresistive looped portions 44 and the connecting loop 42, without significantly affecting the shape anisotropy in those regions.

It will of course be appreciated that the method described with reference to FIGS. 5A-H provides just one example method, and any other suitable methods or process may be used to fabricate the sensors described herein. As one example, methods may involve fabricating the connecting loops 42 first and then depositing and etching the magnetoresistive track 40 such that the magnetoresistive looped portions 44A-B are formed on top of the connecting loops 42 to form the connecting legs.

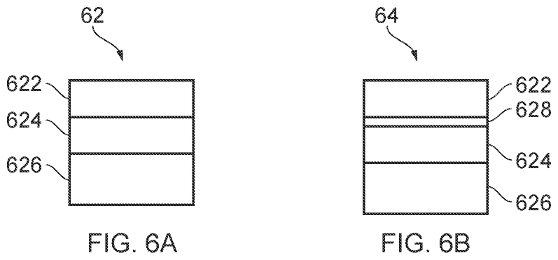

FIGS. 6A-B illustrates example cross sections along the axis X (as shown in FIG. 5G) of the dead end 46 of the divider structure. In a first example cross-section 62 shown in FIG. 6A, the arrangement includes a first layer 622, a second layer 624, and a third layer 626. The first layer 622 is the magnetic material of the connecting loop 42, which may be a ferromagnetic material or some other suitable magnetic material. The second and third layers 624, 626 are the layers that form the magnetoresistive track 40. Specifically, the second layer 624 is the so-called free layer. The free layer 624 is a ferromagnetic layer that is free to align its magnetization with an external magnetic field. The free layer 624 is typically formed of two ferromagnetic layers, for example, a CoFe layer followed by a nickel iron (NiFe) layer. The third layer 626 is a stack of additional layers, at least including a so-called pinned-layer and spacer that sits between the pinned layer and the free-layer 624. The pinned layer typically comprises a ferromagnetic material having a magnetisation that is pinned in a reference direction. The change in film resistance is thus observed when magnetisation direction of the free layer 626 relative to the direction of magnetisation of the pinned layer 626 changes between parallel and anti-parallel.

It will however be appreciated that the connecting legs 46 of the connecting loop 42 and the looped portions 44A-B may be configured with a spacer layer 628 (i.e., spacer layer 52 as described above) therebetween, as illustrated by the example cross section 64 shown in FIG. 6B. Additionally, in cases where the legs of the connecting loops 42 lie in a plane below the legs of the magnetoresistive looped portions 44A-B, the magnetoresistive film may be configured such that the pinned layer 626 is above the free layer 624.

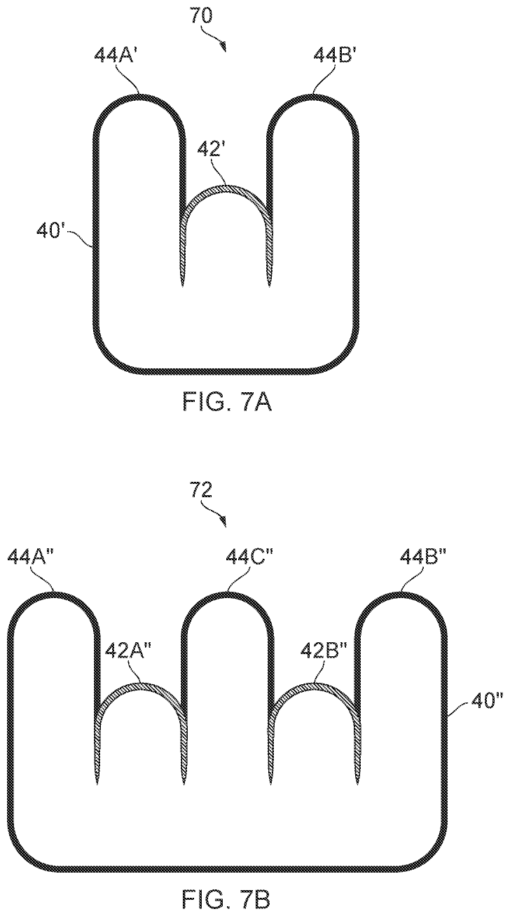

FIGS. 7A and 7B illustrate further possible arrangements 70, 72 of the divider structure in accordance with an example the present disclosure. The first arrangement 70 shows a divider structure arrangement similar to that of FIG. 4, however, the connecting loop 42′ is offset in comparison to the looped portions 44A′-44B′ of the magnetoresistive track 40′. This offset of the connecting loop 42′ allows for a resistance readout of the resistors using electrodes to be taken more easily from just the magnetoresistive track 40′ and thus the connecting loop 42′ does not interfere in the sensor read-out. The second arrangement 72 shows a further divider structure arrangement including the magnetoresistive track 40′ comprising three magnetoresistive looped portions 44A″-44C″ that are connected by two connecting loops 42A″-42B″, both of which are again offset from the magnetoresistive looped portions 44A″-44C″ of the magnetoresistive track 40″.

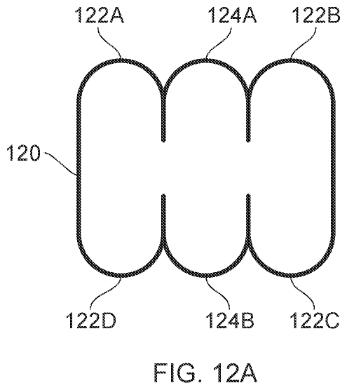

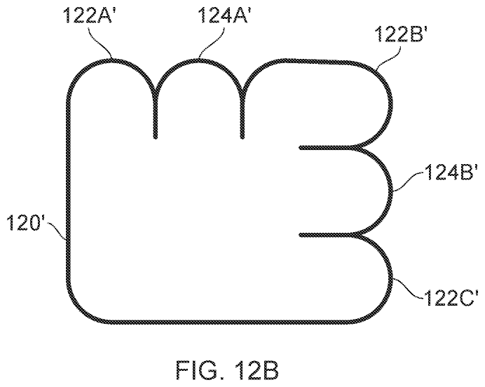

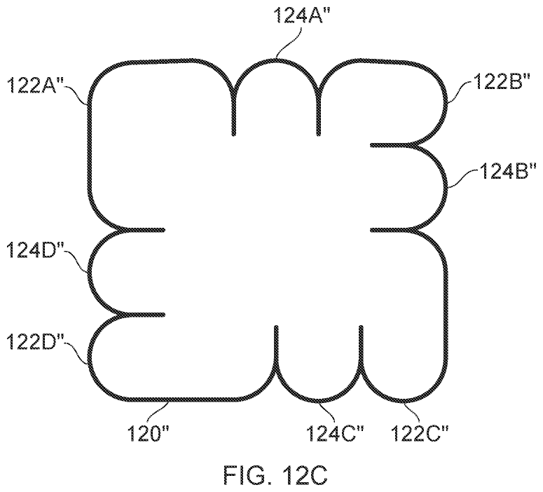

It is worth noting that these just highlight two possible arrangements and many further arrangements are feasible and possible including the presence of a plurality of connecting loops and magnetoresistive looped portions in various configurations, as illustrated further by the arrangements shown in FIGS. 12A-C. For example, FIG. 12A shows a magnetoresistive track 120 comprising four magnetoresistive looped portions 122A-D with two connecting loops 124A-B, wherein one pair of looped portions 122A-B and a connecting loop 124A are provided along one side of the structure, and a second pair of looped portions 122C-D and a connecting loop 124B are provided along the opposite side of the structure. FIG. 12B shows a magnetoresistive track 120′ comprising three magnetoresistive looped portions 122A′-122C′ with two connecting loops 124A′-124B′, wherein one looped portion 122A′ and a connecting loop 124A′ are provided along one side of the structure, and a pair of looped portions 122B′-122C′ and a connecting loop 124B′ are provided along a perpendicular side of the structure. FIG. 12C shows a magnetoresistive track 120″ comprising a plurality of magnetoresistive looped portions 122A″-122D″ and connecting loops 124A″-124D″ that are arranged around the whole perimeter of the structure.

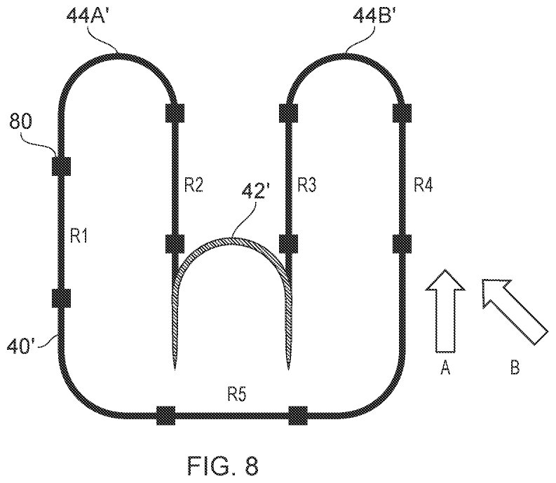

Referring back to FIGS. 7A-B, as discussed above, the offset nature of the connecting loops 42′, 42A″, 42B″ in arrangements 70 and 72 allows for a resistance readout of the resistors using electrodes to be easily taken from the magnetoresistive track 40′, 40″. This is shown by way of example in FIG. 8, which shows how the arrangement 70 of FIG. 7A may be electrically connected at electrical contacts 80 to form resistors R1-R5 (i.e., sensing elements connected in series), from which sensor readings are taken to determine the turn count. As can be seen, no read out points or resistive values are taken from the connecting loop 42′.

It will of course be appreciated that the closed-loop magnetic multi-turn sensor arrangements described herein may be formed on a substrate or printed circuit board (PCB) comprising processing circuitry for processing the turn count signal.

To obtain a read out from the sensor, antiferromagnetic pinning of the reference layer of the magnetoresistive track 40′ is required. In some cases, the resistor denoted R5 may not be used for counting the number of turns. In such cases, a pinning direction as denoted by arrow A is preferred since all of the remaining resistors run parallel to this direction. As a result, in resistors R1-R4, changes in the magnetisation of the free layer between a parallel and anti-parallel direction relative to the pinning direction will result in a readable change in resistance. In contrast, the magnetisation of the free layer in resistor R5 will always be perpendicular to that of the pinning direction, and will therefore not produce a detectable change in resistance. It will of course be appreciated that a pinning direction in the opposite direction (i.e., rotated by 180°) would also be suitable. In other cases, where resistor R5 is also used for measuring the turn count, a pinning direction as denoted by arrow B is preferred, whereby the magnetisation of the reference layers are pinned 45° (in either direction) relative to the resistors R1-R5. In doing so, whilst the magnetisation of the free layer will not be directly parallel or anti-parallel with the pinned direction in in any of the resistors R1-R5, it will still produce a readable change in resistance.

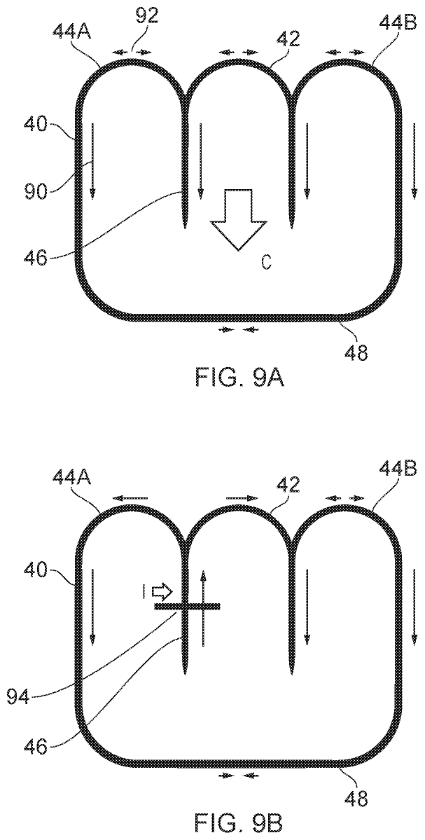

FIGS. 9A-B illustrate an example initialisation processes for initialising the magnetic multi turn sensor upon start-up, using the sensor structure 4 shown in FIG. 4 by way of example, though it will be appreciated that this method of initialisation may be applied to any of the arrangements described herein. In a first step shown in FIG. 9A, the structure 4 is exposed to a strong magnetic field as indicated by arrow C. This causes sensing elements of the magnetoresistive track 40 to become magnetised in the same direction as the external field C, as denoted by arrows 90. This creates domain walls 92 on the top bends (i.e., the bends of the looped portions 44A-B and the connecting loop 42) and along the bottom portion 48 of the track 40. As shown in FIG. 9B, by running a wire 94 on top of one or more of the dead ends 46 and applying a current, the dead end 46 is re-magnetized in the opposite direction, thereby placing the structure 4 in a suitable starting condition for the sensor to start counting. With this principle it would also be possible to write in a unique pattern of domain walls using multiple wires running on the dead ends and re-magnetize to whatever pattern is desired.

As another example, rather than re-magnetizing the dead end 46, the magnetic multi-turn sensor may be initialised by applying a lower current to the wire 94 to stop a domain wall from propagating along that dead-end 46. One rotation of an external magnetic field would stop a domain wall at that point, such that it is annihilated by the next incoming domain wall, to thereby provide the required pattern of domain walls.

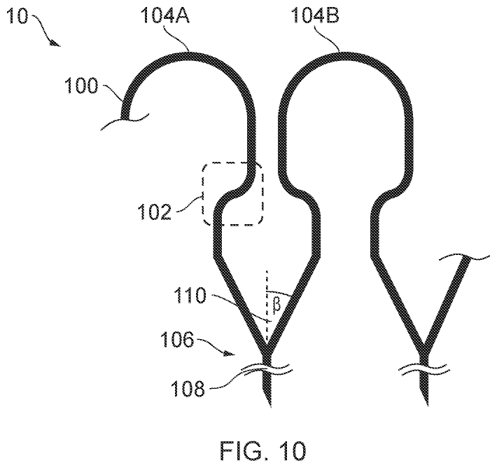

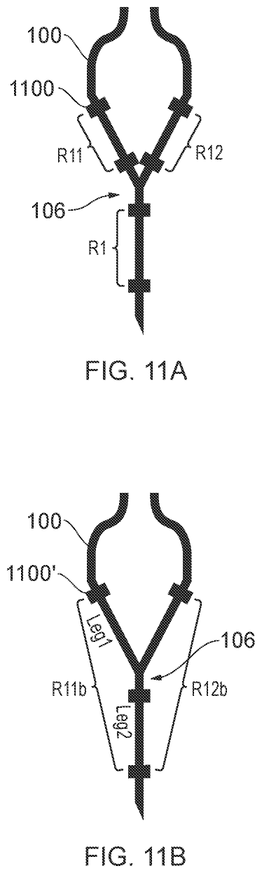

FIG. 10 shows part of a divider structure 10 arrangement including a siphon structure 102 for use with a magnetic multi turn sensor according to a further example the present disclosure. In this example, no connecting loops are provided and the magnetoresistive looped portions 104A-B of the magnetoresistive track 100 are connected directly using a Y-junction 106 as before. However, in order to overcome the problem of uniformity in the magnetoresistive track thickness and the domain wall nucleation that occurs due to the curved nature of a Y-junction 106, a siphon structure is proposed to precede the Y-junction 106 and dead end 108. The siphon structure 102 comprises an S-shaped bend in the magnetoresistive track 100. The angle, curvature, and length of the siphon structure bend 102 is critical and thus is designed such that the angle of incidence of the propagating domain walls into the Y-junction 106 helps to reduce the likelihood of a reduction in the shape anisotropy in this area and reduce the chances of domain wall nucleation at lower fields. Moreover, the angle β, (shown generally at 110) at which the magnetoresistive track 100 enters the Y-junction 106 is important. If angle β 110 is too large then domain wall pinning may occur within the dead end 108 when the stimulus field is rotating. Therefore, the siphon arrangement 102 is designed in order to minimize the angle β 110. The angle β 110 could be, but is not limited to, any angle smaller than 45° relative to the dead end 108. It will be appreciated that the dead end 108 is shown as being short purely for ease of understanding within FIG. 10. In practice, the dead end 108 would be longer than the rest of the siphon structure i.e., longer than the distance from the start of the Y-junction 106 to the S-bend 102, which can be seen more clearly in FIGS. 11A and 11B. In this respect, the length of magnetoresistive track forming the dead end 108 needs to be this long in order to allow space for readout contacts or points from which resistance readings can be taken.

FIGS. 11A and 11B show two examples of resistance readout points that may be used in conjunction with the siphon structure arrangement shown in FIG. 10. In FIG. 11A, the magnetoresistive track 100 around the Y-junction 106 has six readout points 1100 (e.g., in the form of electrical contacts) to form three resistors R11, R12 and R1, from which resistance readings can be taken. In FIG. 11B, the Y-junction 106 has three readout points 1100′ (e.g., in the form of electrical contacts) to form two resistors R11b and R12b, from which resistance readings can be taken. Utilizing R11 and R12 or R11b and R12b allows the system to determine if the last rotation was clockwise or counter-clockwise. This information is not available if only one resistor is used for each Y-junction. For example, the combination in FIG. 11B creates four possible states with three different resistance levels; that is to say, the combinations of the high/low states of the two legs forming the resistors R11b and R12b create four possible states that generate three different combinations of resistance levels. For example, a first state where both R11b and R12b output a high resistance, a second state where R11b outputs a high resistance and R12b outputs a low resistance level, a third state where R11b outputs a low resistance and R12b outputs a high resistance, and a fourth state where both R11b and R12b output a low resistance. For clockwise rotation, the state of R11b will change before R12b, whilst the state of R12b will change before R11b for counter-clockwise rotation.

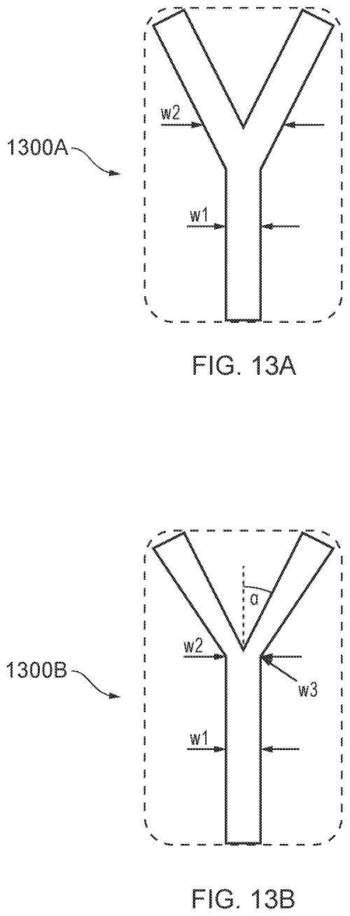

FIGS. 13A-B illustrate a further example in accordance with the present disclosure. As discussed above, in known Y-junctions of divider type structures, such as the Y-junction 1300A shown in FIG. 13A, the width, w2, of the magnetoresistive track in the region of the Y-junction 1300A is significantly larger than the width, w1, of the magnetoresistive track in the rest of the sensor, in particular, the tracks that define the sensing elements of the sensor. As a result, domain wall nucleation occurs in the Y-junction 1300A at a lower external magnetic field than the rest of the sensor, which limits the useful magnetic window of operation (i.e., the range of magnetic field strengths in which the sensor will reliably operate). One further solution, as shown in FIG. 13B, is to provide local narrowing of traces around the Y-junction 1300B to reduce the potential for domain wall nucleation below the upper end of the magnetic window. To do this, the width, w3, of the magnetoresistive track as it approaches the Y-junction 1300B is reduced, such that the width, w2, in the region of the Y-junction 1300B is the same as the rest of the sensor, i.e., width w1. The width w3 of each of the two legs of the Y-junction 1300B depends on the angle (a) at which each leg approaches the Y-junction 1300B. A lower angle will require a larger amount of narrowing, up to half of width w1. A higher angle of approach may therefore be beneficial to ensure that the narrowed portion of the track is not too thin, which may increase the amount of domain wall pinning, which can also limit the minimum field of operation.

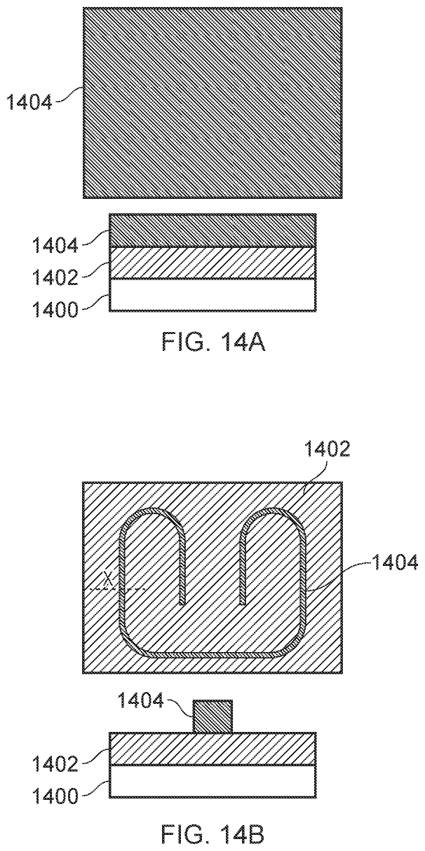

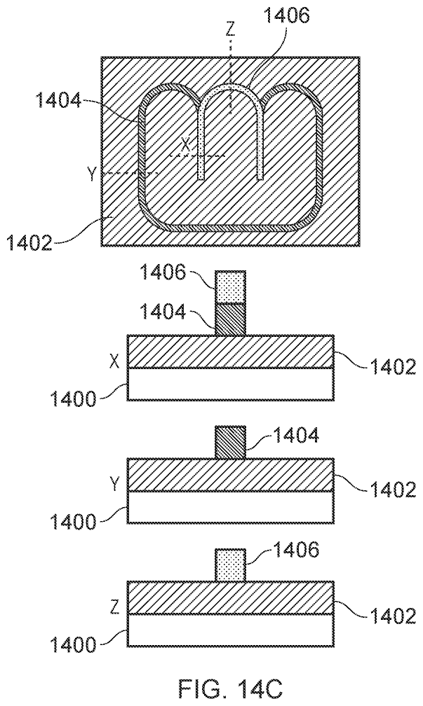

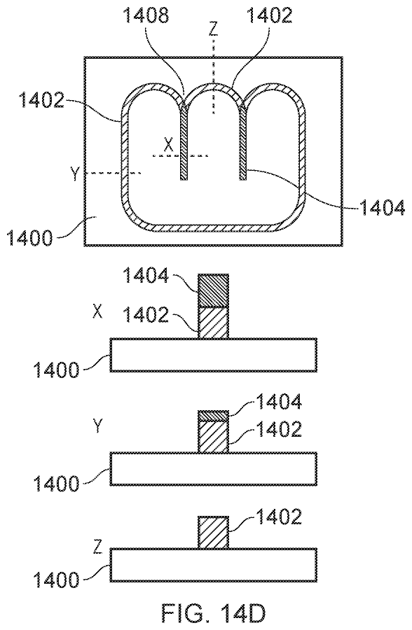

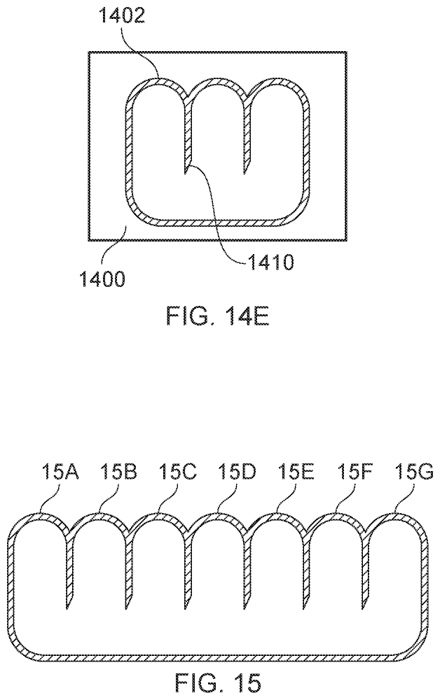

Other techniques may also be used in order to provide narrow tracks and a sharp corner at the Y-junction, for example, using a two-stage electron beam lithography process such as that described in U.S. patent application Ser. No. 18/157,282. One further possible methodology is described with reference to FIGS. 14A-F.

As shown in FIG. 14A, which shows a cross-section and a top-down view, a blanket magnetoresistive film 1402 is deposited on a substrate 1400. In this example, the magnetoresistive film 1402 is a giant magnetoresistive film but it will be appreciated that a tunnel magnetoresistive film may also be used. A dummy layer 1404, also referred to as a hard masking layer, is deposited on the magnetoresistive film 1402, to enable selective etching of the magnetoresistive stack. The dummy layer 1404 may be a single layer of material, such as aluminium oxide (Al2O3) or silicon oxide (SiO2), or a stack comprising multiple layers with the layer adjacent to magnetoresistive film 1402 being very thin and used as an etch stop to indicate that the majority of the dummy layer stack has been etched away. In this respect, laminated dummy layers comprising a non-conductive spacer will help to mitigate a shunting effect at the connection point if a conductive material is used in the dummy layer 1404. Alternatively, in place of the dummy layer 1404, a second spin valve stack may also be provided for additional magnetostatic coupling. In such cases, the second spin valve stack would comprise a full or partial magnetoresistive stack (GMR or TMR) with top layer pinning, that is, a stack having an inverse layer stacking order to that of the magnetoresistive film 1402.

As shown in FIG. 14B, the dummy layer 1404 is patterned and etched to form a partial track. In doing this, the patterned dummy layer 1404 provides a partial track hard mask for the subsequent patterning step, in which the magnetoresistive film 1402 is patterned to form the track of the sensor.

As shown in FIG. 14C, a photoresist layer 1406 is formed at the intersection between the looped portions of the magnetoresistive track, and a lithographic etch is performed to pattern the magnetoresistive film 1402, thereby forming the magnetoresistive track, as shown in FIG. 14D. As shown in FIG. 14D, the resulting magnetoresistive track comprises a plurality of looped portions, similar to those described above. In this respect, the dummy layer 1404 is fully or partially (as shown by Y cross-section) removed by the portions not protected by the photoresist layer 1406. In doing so, a sharp corner at the Y-junction (denoted generally at 1408) between the looped portions of the magnetoresistive track 1402 that were formed using the photoresist 1406 and the looped portions on which the dummy layer 1404 is provided.

Finally, as shown in FIG. 14E, the tips 1410 of the dead ends are sharpened, as described above with reference to FIG. 5G. In some cases, any remaining dummy layer 1404 may be removed, as shown in FIG. 14E, provided the dummy layer 1404 is formed from a material that can be removed through selective etching. Furthermore, as illustrated by FIG. 15, it will be appreciated that the above method may be used to form sensors comprising any suitable number of looped portions. In this example, the resulting sensor will comprise 7 looped portions 15A-G. In such cases, the 1st, 3rd, 5th and 7th looped portions (15A, 15C, 15E and 15G) may be formed using the dummy layer, whilst the 2nd, 4th and 6th looped portions (15B, 15D and 15F) may be formed by using a photoresist layer in those regions.

### Applications

Any of the principles and advantages discussed herein can be applied to other systems, not just to the systems described above. Some embodiments can include a subset of features and/or advantages set forth herein. The elements and operations of the various embodiments described above can be combined to provide further embodiments. The acts of the methods discussed herein can be performed in any order as appropriate. Moreover, the acts of the methods discussed herein can be performed serially or in parallel, as appropriate. While circuits are illustrated in particular arrangements, other equivalent arrangements are possible.

Any of the principles and advantages discussed herein can be implemented in connection with any other systems, apparatus, or methods that benefit could from any of the teachings herein. For instance, any of the principles and advantages discussed herein can be implemented in connection with any devices with a need for correcting rotational angle position data derived from rotating magnetic fields. Additionally, the devices can include any magnetoresistance or Hall effect devices capable of sensing magnetic fields.

Aspects of this disclosure can be implemented in various electronic devices or systems. For instance, phase correction methods and sensors implemented in accordance with any of the principles and advantages discussed herein can be included in various electronic devices and/or in various applications. Examples of the electronic devices and applications can include, but are not limited to, servos, robotics, aircraft, submarines, toothbrushes, biomedical sensing devices, and parts of the consumer electronic products such as semiconductor die and/or packaged modules, electronic test equipment, etc. Further, the electronic devices can include unfinished products, including those for industrial, automotive, and/or medical applications.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The words “coupled” or connected”, as generally used herein, refer to two or more elements that may be either directly connected, or connected by way of one or more intermediate elements. Thus, although the various schematics shown in the figures depict example arrangements of elements and components, additional intervening elements, devices, features, or components may be present in an actual embodiment (assuming that the functionality of the depicted circuits is not adversely affected). The words “based on” as used herein are generally intended to encompass being “based solely on” and being “based at least partly on.” Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values or distances provided herein are intended to include similar values within a measurement error.

While certain embodiments have been described, these embodiments have been presented by way of example only, and are not intended to limit the scope of the disclosure. Indeed, the novel apparatus, systems, and methods described herein may be embodied in a variety of other forms. Furthermore, various omissions, substitutions and changes in the form of the methods and systems described herein may be made without departing from the spirit of the disclosure.

What is claimed is:

1. A closed-loop magnetic multi-turn sensor, comprising:
one or more magnetoresistive tracks comprising a plurality of magnetoresistive looped portions; and
one or more connecting loops for connecting adjacent magnetoresistive looped portions, the one or more connecting loops comprising a track of magnetic material, wherein the magnetoresistive looped portions and the one or more connecting loops are coupled to form a plurality of connecting legs, wherein each connecting leg comprises at least a portion of a magnetoresistive looped portion arranged in a first plane and a portion of a connecting loop formed arranged in a second plane.

2. The closed-loop magnetic multi-turn sensor of claim 1, wherein the second plane is above or below the first plane.

3. The closed-loop magnetic multi-turn sensor of claim 1, wherein the plurality of connecting legs comprise a dead end.

4. The closed-loop magnetic multi-turn sensor of claim 3, wherein each dead end comprises a sharpened end.

5. The closed-loop magnetic multi-turn sensor of claim 1, wherein the plurality of connecting legs each comprise a spacer layer provided between at least a first portion of the magnetoresistive looped portion and a corresponding portion of the respective connecting loop.

6. The closed-loop magnetic multi-turn sensor of claim 5, wherein a second portion of the magnetoresistive looped portion is in direct contact with the respective connecting loop, the second portion being in an end region of the connecting leg.

7. The closed-loop magnetic multi-turn sensor of claim 5, wherein the spacer layer comprises one of: aluminium oxide, silicon nitride, silicon oxide, Tantalum, Ruthenium, Titanium and Titanium Tungsten.

8. The closed-loop magnetic multi-turn sensor of claim 1, wherein the one or more connecting loops are in an offset position relative to the plurality of magnetoresistive looped portions.

9. The closed-loop magnetic multi-turn sensor of claim 1, wherein the one or more connecting loops have a same width as the one or more magnetoresistive tracks.

10. The closed-loop magnetic multi-turn sensor of claim 1, wherein the magnetic material of the one or more connecting loops is a ferromagnetic material.

11. The closed-loop magnetic multi-turn sensor of claim 1, wherein the magnetic material of the one or more connecting loops comprises one of Nickel, Iron, or Cobalt, or an alloy containing at least one of Nickel, Iron, or Cobalt.

12. The closed-loop magnetic multi-turn sensor if claim 1, wherein the one or more magnetoresistive tracks comprises one of: a giant magnetoresistive (GMR) material and a tunnel magnetoresistive (TMR) material.

13. The closed-loop magnetic multi-turn sensor of claim 1, wherein the one or more magnetoresistive tracks and the one or more connecting loops are formed on a substrate.

14. The closed-loop magnetic multi-turn sensor of claim 1, further comprising a plurality of contacts for electrically connecting the one or more magnetoresistive tracks, such that a plurality of magnetoresistive sensor elements connected in series are defined by said contacts.

15. A method of manufacturing a closed-loop magnetic multi-turn sensor, the method comprising:
forming a film of magnetoresistive material on a substrate;
etching the film of magnetoresistive material to form a magnetoresistive track comprising a plurality of magnetoresistive looped portions;
forming, over the magnetoresistive track, a first photoresist layer;
exposing the first photoresist layer to form one or more openings, the one or more openings being formed between adjacent magnetoresistive looped portions; and
depositing a magnetic material in the one or more openings to form one or more connecting loops between adjacent magnetoresistive looped portions, wherein a portion of each connecting loop is coupled to a portion of a magnetoresistive looped portion to form a connecting leg.

16. The method of claim 15, wherein each connecting leg comprises a dead end, the method further comprising sharpening each dead end.

17. The method of claim 15, further comprising depositing a spacer layer between the magnetoresistive looped portions and the one or more connecting loops.

18. The method of claim 17, wherein the spacer layer comprises one of: aluminium oxide, silicon nitride, silicon oxide, Tantalum, Ruthenium, Titanium and Titanium Tungsten.

19. The method of claim 15, wherein the magnetic material is a ferromagnetic material.

20. A closed-loop magnetic multi-turn sensor, comprising:
one or more magnetoresistive tracks comprising a plurality of magnetoresistive looped portions, each magnetoresistive track at least comprising:
a first magnetoresistive looped portion comprising a first S-shaped connecting region and a first straight connecting region; and
a second magnetoresistive looped portion comprising a second S-shaped connecting region and a second straight connecting region;
wherein the second straight connecting region is connected to the first straight connecting region to form a connection point having a portion of magnetoresistive track extending therefrom.
